(19) United States
(12) Patent Application Publication
(10) Pub. No.: US 2023/0030589 A1
(43) Pub. Date: Feb. 2, 2023

(54) SEMICONDUCTOR PACKAGE INCLUDING CHIP CONNECTION STRUCTURE

(71) Applicant: SAMSUNG ELECTRONICS CO., LTD., SUWON-SI (KR)

(72) Inventors: BOIN NOH, SUWON-SI (KR); JEONGHOON AHN, SEONGNAM-SI (KR)

(21) Appl. No.: 17/581,194

(22) Filed: Jan. 21, 2022

(30) Foreign Application Priority Data
Aug. 2, 2021 (KR) 10 2021 0101340

(51) Int. Cl. H01L 23/00; H01L 25/065

(52) U.S. Cl. CPC H01L 24/13; H01L 25/0657; H01L 25/0652; H01L 24/16; H01L 24/14; H01L 24/17; H01L 2924/1436; H01L 2924/1431; H01L 2225/0652; H01L 2225/06548; H01L 2225/06541; H01L 2924/351; H01L 2225/06517; H01L 2225/06513; H01L 2224/16147; H01L 2224/13019; H01L 2224/14051; H01L 2224/17055; H01L 2224/16059; H01L 2224/13553

(57) ABSTRACT

A semiconductor package includes a first semiconductor chip, a second semiconductor chip on the first semiconductor chip, and a first chip connection structure disposed between the first semiconductor chip and the second semiconductor chip. The first chip connection structure includes a first insertion connection structure connected to the first semiconductor chip, a first recess connection structure connected to the second semiconductor chip, and a first contact layer interposed between the first insertion connection structure and the first recess connection structure. The first recess connection structure includes a base and a side wall which defines a recess. A portion of the first insertion connection structure is disposed in the recess. A portion of the first contact layer is disposed in the recess, and the first contact layer covers at least a portion of a bottom surface of the side wall.

### CROSS-REFERENCE TO THE RELATED APPLICATION

This application claims priority from Korean Patent Application No. 10-2021-0101340, filed on Aug. 2, 2021, in the Korean Intellectual Property Office, the disclosure of which is incorporated herein by reference in its entirety.

### BACKGROUND

### 1. Field

The exemplary embodiments of the disclosure relate to a semiconductor package including a chip connection structure.

### 2. Description of the Related Art

As a result of advances in the electronics industries, electronic products are being further miniaturized and multifunctionalized. Accordingly, a semiconductor package in which a plurality of semiconductor chips are vertically stacked has been proposed. Upon stacking semiconductor chips, a metallurgical joint may be formed between a pad and a solder. In such case, failure may occur in a solder joint region due to a difference in the coefficients of thermal expansion among semiconductor chips.

### SUMMARY

The exemplary embodiments of the disclosure provide an enhancement in reliability of a solder joint region interconnecting semiconductor chips included a semiconductor package.

A semiconductor package according to an exemplary embodiment of the disclosure may include a first semiconductor chip, a second semiconductor chip on the first semiconductor chip, and a first chip connection structure disposed between the first semiconductor chip and the second semiconductor chip. The first chip connection structure may include a first insertion connection structure connected to the first semiconductor chip, a first recess connection structure connected to the second semiconductor chip, and a first contact layer interposed between the first insertion connection structure and the first recess connection structure. The first recess connection structure may include a base and a side wall which define a recess. A portion of the first insertion connection structure may be disposed in the recess. A portion of the first contact layer may be disposed in the recess, and the first contact layer covers at least a portion of a bottom surface of the side wall.

A semiconductor package according to an exemplary embodiment of the disclosure may include a first semiconductor chip, a second semiconductor chip on the first semiconductor chip, a first chip connection structure disposed between the first semiconductor chip and the second semiconductor chip, and a mold layer covering the first semiconductor chip and the second semiconductor chip. The first chip connection structure may include a first recess connection structure connected to the first semiconductor chip, a first insertion connection structure connected to the second semiconductor chip, and a first contact layer interposed between the first recess connection structure and the first insertion connection structure. The first recess connection structure may include a base and a side wall which define a recess. A portion of the first insertion connection structure may be disposed in the recess. A portion of the first contact layer may be disposed in the recess, and the first contact layer may cover at least a portion of a top surface of the side wall while being spaced apart from a bottom surface of the second semiconductor chip.

A semiconductor package according to an exemplary embodiments of the disclosure may include a base substrate, a first semiconductor chip on the base substrate, a second semiconductor chip on the first semiconductor chip, a third semiconductor chip on the second semiconductor chip, a first chip connection structure between the first semiconductor chip and the second semiconductor chip, a second chip connection structure between the second semiconductor chip and the third semiconductor chip, and a mold layer disposed on the base substrate while covering the first semiconductor chip, the second semiconductor chip, and the third semiconductor chip. One of the first chip connection structure and the second chip connection structure may include an insertion connection structure, a recess connection structure on the insertion connection structure, and a contact layer between the insertion connection structure and the recess connection structure. The first chip connection structure and the second chip connection structure may have mirror symmetry with respect to each other.

### BRIEF DESCRIPTION OF THE DRAWINGS

FIG. 1 is a sectional view of a semiconductor package according to an exemplary embodiment of the disclosure.

FIG. 2A is an enlarged view of a portion A of FIG. 1.

FIG. 2B is an enlarged view of a portion A of FIG. 1 according to an exemplary embodiment of the disclosure.

FIG. 3 is a sectional view of a semiconductor package according to an exemplary embodiment of the disclosure.

FIG. 4 is a sectional view of a semiconductor package according to an exemplary embodiment of the disclosure.

FIG. 5 is an enlarged view of a portion B of FIG. 4.

FIG. 6 is a sectional view of a semiconductor package according to an exemplary embodiment of the disclosure.

FIG. 7 is a sectional view of a semiconductor package according to an exemplary embodiment of the disclosure.

FIG. 8 is a sectional view of a semiconductor package according to an exemplary embodiment of the disclosure.

FIG. 9A is a sectional view of a semiconductor package according to an exemplary embodiment of the disclosure.

FIG. 9B is a sectional view of a semiconductor package according to an exemplary embodiment of the disclosure.

FIGS. 10 to 17 are sectional views showing a semiconductor package manufacturing method according to an exemplary embodiment of the disclosure.

FIGS. 12A to 12L are views showing methods of manufacturing a recess connection structure and a contact layer in accordance with an exemplary embodiment of the disclosure.

FIGS. 15A to 15E are sectional views showing a method of manufacturing an insertion connection structure in accordance with an exemplary embodiment of the disclosure.

### DETAILED DESCRIPTION OF EXEMPLARY EMBODIMENTS

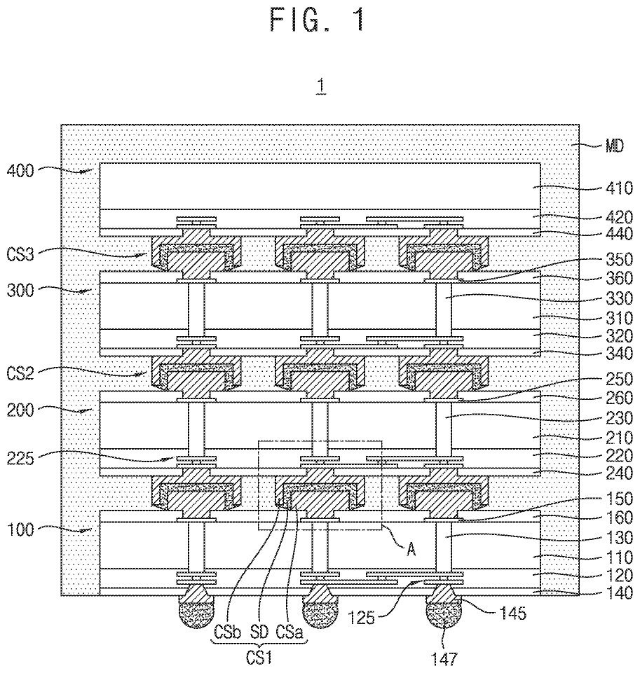

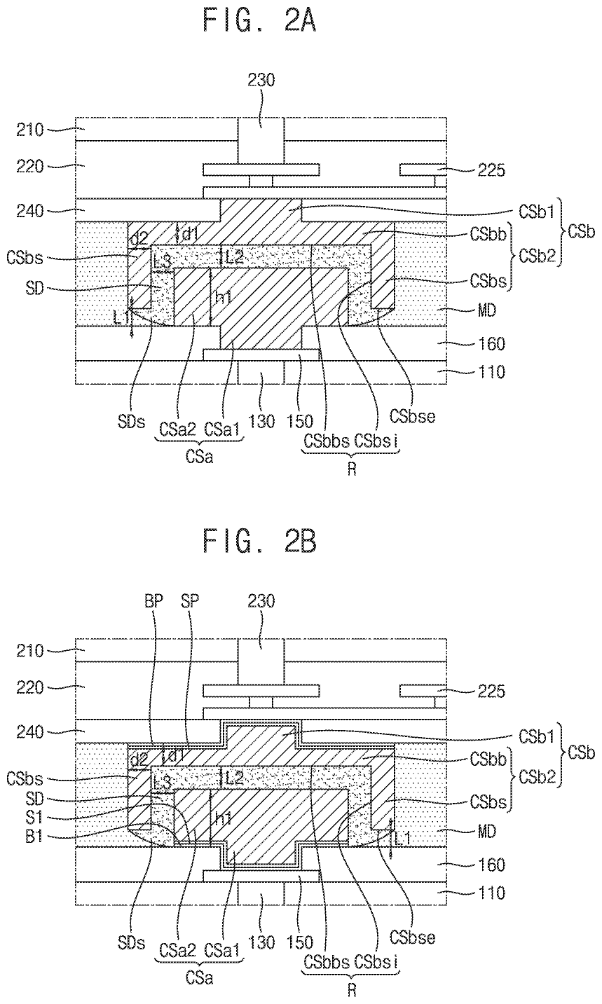

FIG. 1 is a sectional view of a semiconductor package according to an exemplary embodiment of the disclosure. FIG. 2A is an enlarged view of a portion A of FIG. 1.

Referring to FIG. 1, a semiconductor package 1 may include a first semiconductor chip 100, a second semiconductor chip 200, a third semiconductor chip 300, and a fourth semiconductor chip 400 which are vertically stacked. Each of the first to fourth semiconductor chips 100, 200, 300, and 400 may have a bottom surface and a top surface which are opposite to each other. The first to fourth semiconductor chips 100, 200, 300, and 400 may be stacked such that top and bottom surfaces of adjacent ones thereof face each other. Although the semiconductor package in which the first to fourth semiconductor chips 100, 200, 300, and 400 are stacked is illustratively shown in FIG. 1, the number of semiconductor chips stacked in the semiconductor package 1 according to the exemplary embodiment of the disclosure is not limited thereto.

The first to fourth semiconductor chips 100, 200, 300, and 400 may be a logic chip and/or a memory chip. For example, all of the first to fourth semiconductor chips 100, 200, 300, and 400 may be memory chips of the same kind, or a part of the first to fourth semiconductor chips 100, 200, 300, and 400 may be a memory chip, and the other part of the first to fourth semiconductor chips 100, 200, 300, and 400 may be a logic chip. The memory chip may be, for example, a volatile memory chip such as a dynamic random access memory (DRAM) or a static random access memory (SRAM), or a non-volatile memory chip such as a phase-change random access memory (PRAM), a magnetoresistive random access memory (MRAM), a ferroelectric random access memory (FeRAM), or a resistive random access memory (RRAM). In addition, the logic chip may be, for example, a microprocessor, an analog device, or a digital signal processor. In some exemplary embodiments, each of the first to fourth semiconductor chips 100, 200, 300, and 400 may be a high bandwidth memory (HBM) DRAM.

The first semiconductor chip 100 may include a first semiconductor substrate 110, a first semiconductor element layer 120, a first through electrode 130, a first lower passivation layer 140, a lower connection structure 145, a connection terminal 147, a first upper pad 150, and a first upper passivation layer 160.

The first semiconductor substrate 110 may include silicon. Alternatively, the first semiconductor substrate 110 may include a semiconductor element such as germanium, or a compound semiconductor such as silicon carbide (SiC), gallium arsenide (GaAs), indium arsenide (InAs) and indium phosphide (InP). Otherwise, the first semiconductor substrate 110 may have a silicon-on-insulator (SOI) structure. For example, the first semiconductor substrate 110 may include a buried oxide layer (BOX layer). The first semiconductor substrate 110 may include a conductive region, for example, a well doped with impurities, or a structure doped with impurities. In addition, the first semiconductor substrate 110 may have various element isolation structures such as a shallow trench isolation (STI) structure.

The first semiconductor substrate 110 may have a top surface and a bottom surface which are opposite to each other. The first semiconductor element layer 120 may be disposed at the side of the bottom surface of the first semiconductor substrate 110. The first semiconductor element layer 120 may include a first wiring structure 125 for connecting a plurality of individual elements to other wirings formed at the first semiconductor substrate 110. The first wiring structure 120 may include a metal wiring layer and a via plug.

The first through electrode 130 may extend through the first semiconductor substrate 110, and may extend from the top surface of the first semiconductor substrate 110 toward the bottom surface of the first semiconductor substrate 110. The first through electrode 130 may extend into the first semiconductor element layer 120. The first through electrode 130 may be connected to the first wiring structure 125 provided in the first semiconductor element layer 120, or may be directly connected to the lower connection structure 145 while extending through the first semiconductor element layer 120. The first semiconductor element layer 120 may be connected to the first upper pad 150 which is disposed on the top surface of the first semiconductor substrate 110. The through electrode 130 may have a pillar shape.

The first lower passivation layer 140 may cover a bottom surface of the first semiconductor element layer 120. For example, the first lower passivation layer 140 may be formed of an insulating layer made of photosensitive polyimide (PSPI), SiN, tetraethyl orthosilicate (TEOS), or the like.

The lower connection structure 145 may be disposed on a bottom surface of the first lower passivation layer 140. A portion of the lower connection structure 145 may be connected to the first semiconductor element layer 120 while extending through the first lower passivation layer 140. The lower connection structure 145 may be connected to the first wiring structure 125 of the first semiconductor element layer 120. For example, the lower connection structure 145 may include at least one of aluminum, copper, nickel, tungsten, platinum, and gold.

The connection terminal 147 may be disposed on the lower connection structure 145. The connection terminal 147 may be used to electrically connect the semiconductor package 1 to an external substrate. For example, the first connection terminal 147 may include a pillar structure, a ball structure, or a solder layer. The first upper pad 150 may be disposed on the top surface of the first semiconductor substrate 110. The first upper pad 150 may include the same material as the lower connection structure 145. The first upper passivation layer 160 may be disposed on the top surface of the first semiconductor substrate 110. The first upper passivation layer 160 may cover a portion of the first upper pad 150. The first upper passivation layer 160 may include the same material as the first lower passivation layer 140, or may include a material different from that of the first lower passivation layer 140.

The second semiconductor chip 200 may be disposed on the top surface of the first semiconductor chip 100. The second semiconductor chip 200 may include a second semiconductor substrate 210, a second semiconductor element layer 220, a second through electrode 230, a second lower passivation layer 240, a second upper pad 250, and a second upper passivation layer 260.

The third semiconductor chip 300 may be disposed on the top surface of the second semiconductor chip 200. The third semiconductor chip 300 may include a third semiconductor substrate 310, a third semiconductor element layer 320, a third through electrode 330, a third lower passivation layer 340, a third upper pad 350, and a third upper passivation layer 360.

The fourth semiconductor chip 400 may be disposed on the top surface of the third semiconductor chip 300. The fourth semiconductor chip 400 may include a fourth semiconductor substrate 410, a fourth semiconductor element layer 420, and a fourth lower passivation layer 440. The fourth semiconductor chip 400 may omit a through electrode, an upper pad, and an upper passivation layer, in contrast to the other semiconductor chips.

The second to fourth semiconductor chips 200, 300 and 400 may have technical characteristics identical or similar to those of the first semiconductor chip 100 and, as such, description of the second to fourth semiconductor chips 200, 300 and 400 may be replaced by the description of the first semiconductor chip 100.

The semiconductor package 1 may include a first chip connection structure CS1, a second chip connection structure CS2, and a third chip connection structure CS3. The second semiconductor chip 200 may be mounted on the first semiconductor chip 100 via the first chip connection structure CS1. The third semiconductor chip 300 may be disposed on the second semiconductor chip 200 via the second chip connection structure CS2. The fourth semiconductor chip 400 may be disposed on the third semiconductor chip 300 via the third chip connection structure CS3.

The first chip connection structure CS1 may include a first insertion connection structure CSa, a first recess connection structure CSb, and a first contact layer SD. The first insertion connection structure CSa may be disposed on the top surface of the first semiconductor chip 100, and may be connected to the first semiconductor chip 100. The first recess connection structure CSb may be disposed on the bottom surface of the second semiconductor chip 200, and may be connected to the second semiconductor chip 200. The first recess connection structure CSb may be disposed on the first insertion connection structure CSa. The first recess connection structure CSb may be disposed to vertically overlap with the first insertion connection structure CSa corresponding thereto. At least a portion of the first contact layer SD may be interposed between the first insertion connection structure CSa and the first recess connection structure CSb. The first contact layer SD may surround an upper portion of the first insertion connection structure CSa, and may cover a portion of the first recess connection structure CSb. For example, the first insertion connection structure CSa may include at least one of nickel (Ni), gold (Au), and copper (Cu). The first recess connection structure CSb may include nickel (Ni) and/or copper (Cu). The first contact layer SD may be a solder. For example, the first contact layer SD may be a solder including tin (Sn) and at least one metal material. For example, the first contact layer SD may include at least one of SnAg, SnBi, SnCu, and SnIn.

Referring to FIG. 2A, the first insertion connection structure CSa may include a first section CSa1 and a second section CSa2. The first section CSa1 of the first insertion connection structure CSa may extend through the first upper passivation layer 160 and, as such, may be connected to the first upper pad 150. The second section CSa2 of the first insertion connection structure CSa may be disposed on the first section CSa1, and may have a greater width than the first section CSa1. The second section CSa2 of the first insertion connection structure CSa may be disposed on a top surface of the first upper passivation layer 160. For example, a height h1 of the second section CSa2 may be about 2 to 50 μm.

The first recess connection structure CSb may be disposed on the first insertion connection structure CSa, and may be spaced apart from the first insertion connection structure CSa. The first recess connection structure CSb may include a first section CSb1 and a second section CSb2. The first section CSb1 may extend into the second lower passivation layer 240. The first section CSb1 may extend through the second lower passivation layer 240 and, as such, may be connected to the second semiconductor element layer 220. For example, the first section CSb1 may be connected to a second wiring structure 225 included in the second semiconductor element layer 220.

The second section CSb2 may be disposed on the first section CSb1. The second section CSb2 may be disposed on a bottom surface of the second lower passivation layer 240. The second section CSb2 may include a base CSbb and a side wall CSbs. The base CSbb may be directly connected to the first section CSb1. A top surface of the base CSbb may contact the bottom surface of the second lower passivation layer 240. The width of the base CSbb may be greater than the width of the second section CSa2 of the first insertion connection structure CSa. The side wall CSbs may be connected to an edge of the base CSbb. The side wall CSbs may extend from the base CSbb toward the first semiconductor chip 100. The base CSbb and the side wall CSbs may define a recess R. The recess R may be defined by a bottom surface CSbbs of the base CSbb and an inner side surface CSbsi of the side wall CSbs. Each of a thickness d1 of the base CSbb and a thickness d2 of the side wall CSbs may be about 2 to 48 μm. The thickness d1 of the base CSbb and the thickness d2 of the side wall CSbs may differ from each other. A height h2 of the side wall CSbs may be 2 to 48 μm. In an exemplary embodiment, the height h2 of the side wall CSbs may be equal to or greater than the height h1 of the second section CSa2 of the first insertion connection structure CSa. The overall height d1+h2 of the second section CSb2 of the first recess connection structure CSb may be 50 μm at maximum. The side wall CSbs may be spaced apart from the first upper passivation layer 160 of the first semiconductor chip 100. A first minimum distance L1 between a bottom surface CSbse of the side wall CSbs and the first upper passivation layer 160 may be about 2 to 20 μm.

A portion of the second section CSa2 of the first insertion connection structure CSa may be disposed in the recess R of the first recess connection structure CSb. A portion of the second section CSa2 of the first insertion connection structure CSa may horizontally overlap with a portion of the side wall CSbs of the first recess connection structure CSb. The second section CSa2 of the first insertion connection structure CSa may be spaced apart from the first recess connection structure CSb by a predetermined distance, and the first insertion connection structure CSa and the first recess connection structure CSb may not directly contact each other. A second minimum distance L2 between a top surface of the first insertion connection structure CSa and a bottom surface of the base CSbb of the first recess connection structure CSb may be about 2 to 20 μm. The second minimum distance L2 may be equal to or different from the first minimum distance L1. A third minimum distance L3 between a side surface of the first insertion connection structure CSa and the inner side surface CSbsi of the first recess connection structure CSb may be about 2 to 20 μm. The third minimum distance L3 may be equal to or different from the first minimum distance L1 and/or the second minimum distance L2.

The first contact layer SD may be interposed between the first insertion connection structure CSa and the first recess connection structure CSb. A portion of the first contact layer SD may be disposed between the top surface of the first insertion connection structure CSa and the bottom surface CSbbs of the base CSbb of the first recess connection structure CSb. A portion of the first contact layer SD may be disposed between the side surface of the first insertion connection structure CSa and the inner side surface CSbsi of the first recess connection structure CSb. The first contact layer SD may contact a side surface and a top surface of the second section CSa2 of the first insertion connection structure CSa. The first contact layer SD may completely cover the side surface and the top surface of the second section CSa2 of the first insertion connection structure CSa. The first contact layer SD may contact the bottom surface CSbbs of the base CSbb, the inner side surface CSbsi of the side wall CSbs, and the bottom surface CSbse of the side wall CSbs in the first recess connection structure CSb. The first contact layer SD may completely cover the bottom surface CSbbs of the base CSbb and the inner side surface CSbsi of the side wall CSbs in the first recess connection structure CSb. The first contact layer SD may cover at least a portion of the bottom surface CSbse of the side wall CSbs of the first recess connection structure CSb. In an exemplary embodiment, the first contact layer SD may completely cover the bottom surface CSbse of the side wall CSbs of the first recess connection structure CSb. The first contact layer SD may be spaced apart from the first semiconductor chip 100. The first contact layer SD may be spaced apart from the first upper passivation layer 160. A lowermost surface SDs of the first contact layer SD may be inclined. An angle formed by the lowermost surface SDs of the first contact layer SD and the top surface of the first upper passivation layer 160 may be an acute angle. The lowermost surface SDs of the first contact layer SD may be a curved surface. The lowermost surface SDs of the first contact layer SD may interconnect the side surface of the second section CSa2 of the first insertion connection structure CSa and the bottom surface CSbse of the side wall CSbs of the first recess connection structure CSb. In an exemplary embodiment, the lowermost surface SDs of the first contact layer SD may interconnect a lower end of the side surface of the second section CSa2 of the first insertion connection structure CSa and a lower end of an outer side surface of the side wall CSbs of the first recess connection structure CSb.

The second and third chip connection structures CS2 and CS3 may have technical characteristics identical to those of the first chip connection structure CS1 and, as such, descriptions of the second and third chip connection structures CS2 and CS3 may be replaced by the description of the first chip connection structure CS1.

Referring to FIGS. 1 and 2A, the semiconductor package 1 may further include a mold layer MD covering the first to fourth semiconductor chips 100, 200, 300, and 400. The mold layer MD may cover portions of the top and bottom surfaces of the second to fourth semiconductor chips 200, 300 and 400, and side surfaces of the second to fourth semiconductor chips 200, 300 and 400. The mold layer MD may cover a side surface of the first semiconductor chip 100, and may cover a portion of the top surface of the first semiconductor chip 100. The mold layer MD may expose the bottom surface of the first semiconductor chip 100. A portion of the mold layer MD may be disposed to surround the first to third chip connection structures CS1, CS2 and CS3 among the first to fourth semiconductor chips 100, 200, 300 and 400. The mold layer MD may contact the first to third chip connection structures CS1, CS2 and CS3. The mold layer MD may contact an outer side surface of the recess connection structure of each of the first to third chip connection structures CS1, CS2 and CS3. The mold layer MD may contact the lowermost surface of the contact layer of each of the first to third chip connection structures CS1, CS2 and CS3. For example, the mold layer MD may be interposed between the lowermost surface SDs of the first contact layer SD of the first chip connection structure CS1 and the first upper passivation layer 160. For example, the mold layer MD may include an epoxy molding compound.

FIG. 2B is an enlarged view of a portion A of FIG. 1 according to an exemplary embodiment of the disclosure.

Referring to FIG. 2B, the first insertion connection structure CSa may include a barrier pattern B1 and a seed pattern S1. The barrier pattern B1 and the seed pattern S1 may constitute a lower portion of the first insertion connection structure CSa. Each of the barrier pattern B1 and the seed pattern S1 may extend along a bottom surface of the first insertion connection structure CSa. The barrier pattern B1 may directly contact the first upper pad 150 and the first upper passivation layer 160, and the seed pattern S1 may be disposed on the barrier pattern B1. For example, the barrier pattern B1 may include titanium (Ti), and the seed pattern S1 may include copper (Cu). Portions constituting the first insertion connection structure CSa, except for the barrier pattern B1 and the seed pattern S1, may be made of at least one of nickel (Ni), gold (Au), and copper (Cu). In an exemplary embodiment, the seed pattern S1 may be omitted.

The first recess connection structure CSb may further include a barrier pattern BP and a seed pattern SP. The barrier pattern BP and the seed pattern SP may constitute an upper portion of the first recess connection structure CSb. The barrier pattern BP and the seed pattern SP may extend along a top surface of the first recess connection structure CSb. The barrier pattern BP may directly contact the second lower passivation layer 240 and the second semiconductor element layer 220, and the seed pattern SP may be formed on the barrier pattern BP. For example, the barrier pattern BP may include titanium (Ti), and the seed pattern SP may include copper (Cu). Portions constituting the first recess connection structure CSb, except for the barrier pattern BP and the seed pattern SP, may be made of nickel (Ni) or copper (Cu). In an exemplary embodiment, the seed pattern SP may be omitted.

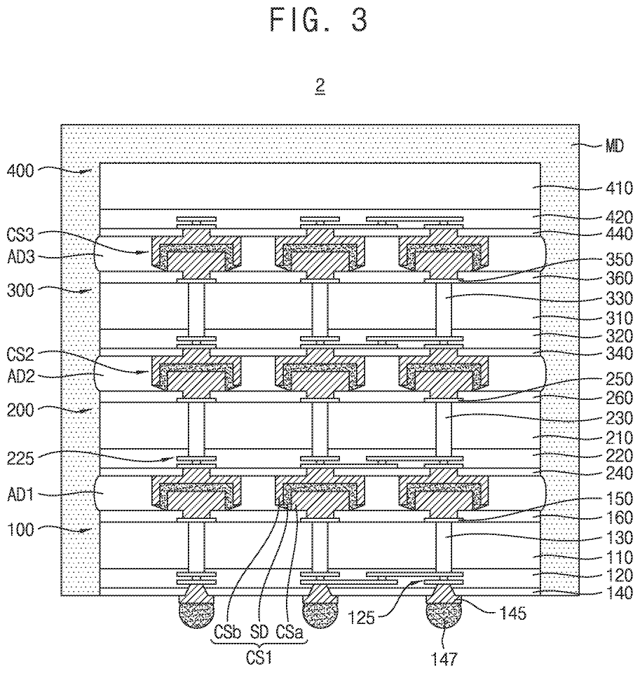

FIG. 3 is a sectional view of a semiconductor package according to an exemplary embodiment of the disclosure.

Referring to FIG. 3, a semiconductor package 2 differs from the semiconductor package 1 described with reference to FIG. 1 in that the semiconductor package 2 further includes a first insulating layer AD1, a second insulating layer AD2, and a third insulating layer AD3. The first insulating layer AD1 may be disposed to surround a first chip connection structure CS1 between a first semiconductor chip 100 and a second semiconductor chip 200. The second insulating layer AD2 may be disposed to surround a second chip connection structure CS2 between the second semiconductor chip 200 and a third semiconductor chip 300. The third insulating layer AD3 may be disposed to surround a third chip connection structure CS3 between the third semiconductor chip 300 and a fourth semiconductor chip 400. For example, the first to third insulating layers AD1, AD2, and AD3 may be an insulating polymer. The first to third insulating layers AD1, AD2, and AD3 may contact contact layers included in the first to third connection structures CS1, CS2, and CS3, respectively. For example, the first insulating layer AD1 may contact a lowermost surface SDs of a first contact layer SD included in the first chip connection structure CS1.

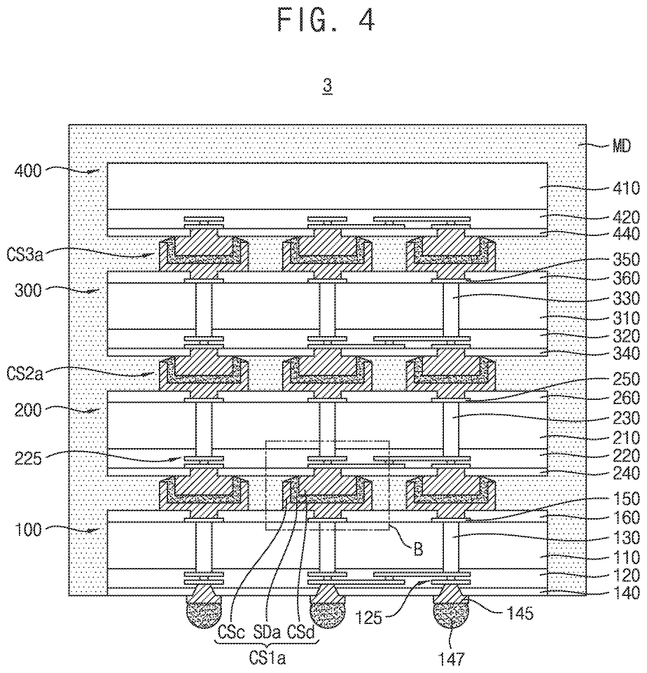

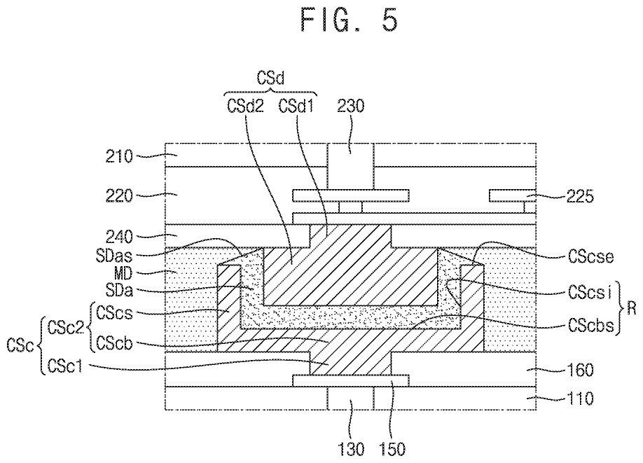

FIG. 4 is a sectional view of a semiconductor package according to an exemplary embodiment of the disclosure. FIG. 5 is an enlarged view of a portion B of FIG. 4.

Referring to FIG. 4, a semiconductor package 3 differs from the semiconductor package 1 described with reference to FIG. 1 in that the semiconductor package 3 includes chip connection structures having structures different from those of the first to third chip connection structures CS1, CS2, and CS3 included in the semiconductor package 1 described with reference to FIG. 1. Chip connection structures CS1a, CS2a, and CS3a included in the semiconductor package 3 of FIG. 4 may have vertical mirror symmetry with the first to third chip connection structures CS1, CS2, and CS3 included in the semiconductor package 1 described with reference to FIG. 1, respectively. For example, although the first recess connection structure CSb is disposed over the first insertion connection structure CSa in the first chip connection structure CS1 included in the semiconductor package 1 described with reference to FIG. 1, a first insertion connection structure CSd may be disposed over a first recess connection structure CSc in the semiconductor package 3 of FIG. 4. The chip connection structure as described with reference to FIG. 1 may be referred to as a first type chip connection structure. The chip connection structure as described with reference to FIG. 4 may be referred to as a second type chip connection structure.

In an exemplary embodiment, the first chip connection structure CS1a may be disposed between a first semiconductor chip 100 and a second semiconductor chip 200. Referring to FIGS. 4 and 5, the first chip connection structure CS1a may include the first recess connection structure CSc, which is connected to the first semiconductor chip 100, the first insertion connection structure CSd, which is connected to the second semiconductor chip 200, and a first contact layer SDa disposed between the first insertion connection structure CSd and the first recess connection structure CSc.

The first recess connection structure CSc may be disposed on a first upper passivation layer 160. The first recess connection structure CSc may include a first section CSc1 and a second section CSc2. The first section CSc1 may extend into the first upper passivation layer 160. The first section CSc1 may extend through the first upper passivation layer 160 and, as such, may be connected to a first upper pad 150.

The second section CSc2 may be disposed on the first section CSc1. The second section CSc2 may be disposed on a top surface of the first upper passivation layer 160. The second section CSc2 may include a base CScb and a side wall CScs. The base CScb may be directly connected to the first section CSc1. A bottom surface of the base CScb may contact the top surface of the first upper passivation layer 160. The width of the base CScb may be greater than the width of the first section CSc1. The side wall CScs may be connected to an edge of the base CScb. The side wall CScs may extend from the base CScb toward the second semiconductor chip 200. The base CScb and the side wall CScs may define a recess R. The recess R may be defined by a top surface CScbs of the base CScb and an inner side surface CScsi of the side wall CScs. The side wall CScs may be spaced apart from a second lower passivation layer 240 of the second semiconductor chip 200.

The first insertion connection structure CSd may be disposed on the first recess connection structure CSc, and may be spaced apart from the first recess connection structure CSc. The first insertion connection structure CSd may include a first section CSd1 and a second section CSd2. The first section CSd1 of the first insertion connection structure CSd may extend through the second lower passivation layer 240 and, as such, may be connected to a second semiconductor element layer 220 of the second semiconductor chip 200. The first section CSd1 of the first insertion connection structure CSd may be connected to a second wiring structure 225 of the second semiconductor element layer 220. The second section CSd2 of the first insertion connection structure CSd may be disposed under the first section cSd1, and may have a greater width than the first section CSd1. The second section CSd2 of the first insertion connection structure CSd may be disposed on a bottom surface of the second lower passivation layer 240.

A portion of the second section CSd2 of the first insertion connection structure CSd may be disposed in the recess R of the first recess connection structure CSc. A portion of the second section CSd2 of the first insertion connection structure CSd may horizontally overlap with a portion of the side wall CScs of the first recess connection structure CSc. The second section CSd2 of the first insertion connection structure CSd may be spaced apart from the first recess connection structure CSc by a predetermined distance, and the first insertion connection structure CSd and the first recess connection structure CSc may not directly contact each other.

The first contact layer SDa may be interposed between the first recess connection structure CSc and the first insertion connection structure CSd. A portion of the first contact layer SDa may be interposed between a top surface of the first insertion connection structure CSd and the top surface CScbs of the base CScb of the first recess connection structure CSc. A portion of the first contact layer SDa may be interposed between a side surface of the first insertion connection structure CSd and the inner side surface CScsi of the first recess connection structure CSc. The first contact layer SDa may contact a side surface and a top surface of the second section CSd2 of the first insertion connection structure CSd. The first contact layer SDa may completely cover the side surface and the top surface of the second section CSd2 of the first insertion connection structure CSd. The first contact layer SDa may contact the top surface CScbs of the base CScb, the inner side surface CScsi of the side wall CScs, and a top surface CScse of the side wall CScs in the first recess connection structure CSc. The first contact layer SDa may completely cover the top surface CScbs of the base CScb and the inner side surface CScsi of the side wall CScs in the first recess connection structure CSc. The first contact layer SDa may cover at least a portion of the top surface CScse of the side wall CScs of the first recess connection structure CSc. In an exemplary embodiment, the first contact layer SDa may completely cover the top surface CScse of the side wall CScs of the first recess connection structure CSc. The first contact layer SDa may be spaced apart from the second semiconductor chip 200. The first contact layer SDa may be spaced apart from the second lower passivation layer 240. An uppermost surface SDas of the first contact layer SDa may be inclined. An angle formed by the uppermost surface SDas of the first contact layer SDa and the second lower passivation layer 240 may be an acute angle. The uppermost surface SDas of the first contact layer SDa may be a curved surface. The uppermost surface SDas of the first contact layer SDa may interconnect a side surface of the second section CSd2 of the first insertion connection structure CSd and the top surface CScse of the side wall CScs of the first recess connection structure CSc. In an exemplary embodiment, the uppermost surface SDas of the first contact layer SDa may interconnect an upper end of the side surface of the second section CSd2 of the first insertion connection structure CSd and an upper end of an outer side surface of the side wall CScs of the first recess connection structure CSc.

The second chip connection structure CS2a may be disposed between the second semiconductor chip 200 and a third semiconductor chip 300, and the third chip connection structure CS3a may be disposed between the third semiconductor chip 300 and a fourth semiconductor chip 400. The second and third chip connection structures CS2a and CS3a may have technical characteristics identical to those of the first chip connection structure CS1a.

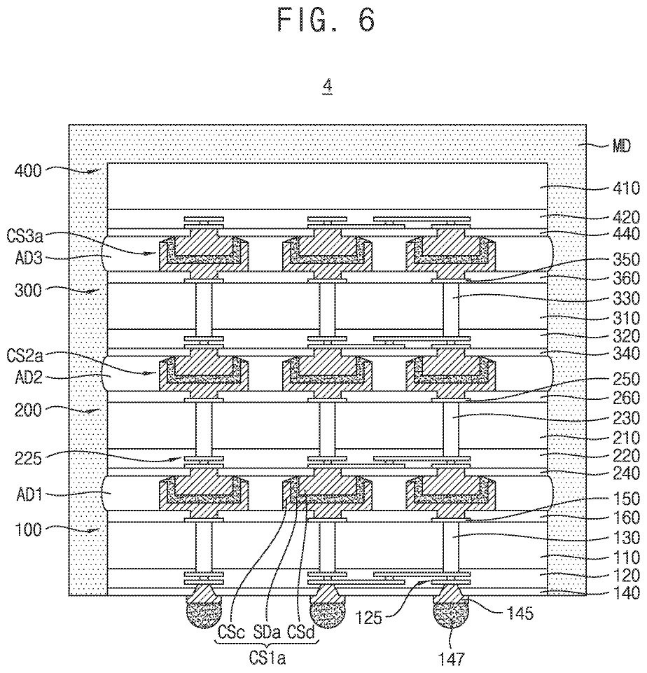

FIG. 6 is a sectional view of a semiconductor package according to an exemplary embodiment of the disclosure.

Referring to FIG. 6, a semiconductor package 4 differs from the semiconductor package 3 described with reference to FIG. 4 in that the semiconductor package 4 further includes first to third insulating layers AD1, AD2, and AD3. The first to third insulating layers AD1, AD2, and AD3 may have technical characteristics identical or similar to those of the first to third insulating layers AD1, AD2, and AD3 described with reference to FIG. 3.

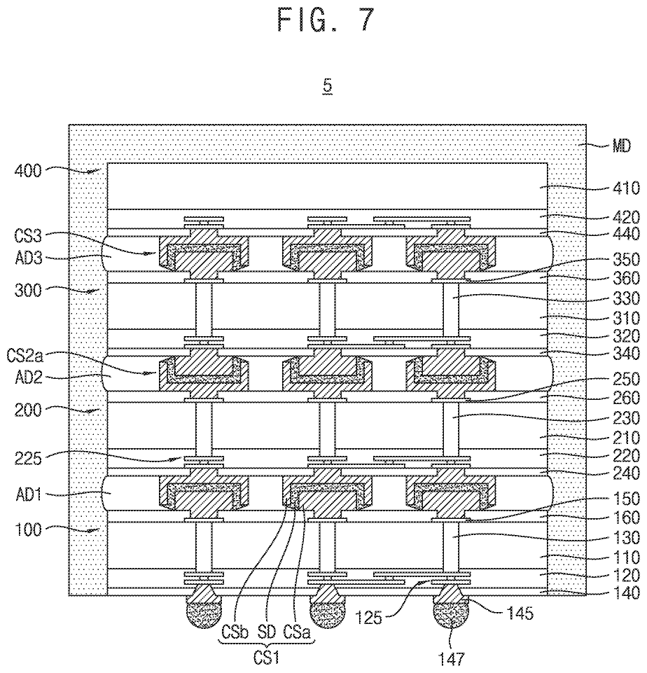

FIG. 7 is a sectional view of a semiconductor package according to an exemplary embodiment of the disclosure.

Referring to FIG. 7, a semiconductor package 5 may include chip connection structures having different structures. The semiconductor package 5 may include both the first type chip connection structure and the second type chip connection structure. In an exemplary embodiment, the semiconductor package 5 may include a first chip connection structure CS1 between a first semiconductor chip 100 and a second semiconductor chip 200, a second chip connection structure CS2a between the second semiconductor chip 200 and a third semiconductor chip 300, and a third chip connection structure CS3 between the third semiconductor chip 300 and a fourth semiconductor chip 400, and one or two of the first to third chip connection structures CS1, CS2a, and CS3 may be the first type chip connection structure, and the remaining ones or one of the first to third chip connection structures CS1, CS2a, and CS3 may be the second type chip connection structure. For example, in FIG. 7, the first chip connection structure CS1 and the third chip connection structure CS3 may be the first type chip connection structure, and the second chip connection structure CS2a may be the second type chip connection structure. As such, the first chip connection structure CS1 and the third chip connection structure CS3 may have characteristics of the chip connection structures described with reference to FIGS. 1 and 2A, and the second chip connection structure CS2a may have characteristics of the chip connection structures described with reference to FIGS. 4 and 5.

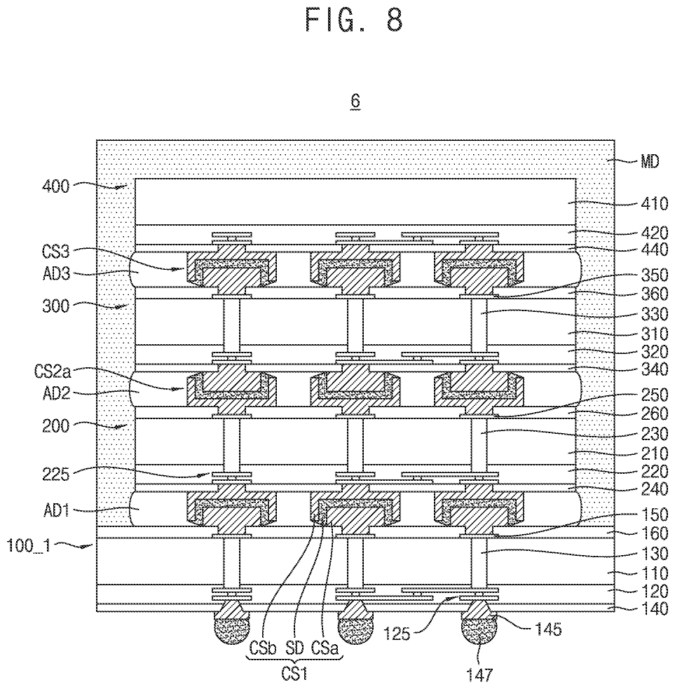

FIG. 8 is a sectional view of a semiconductor package according to an exemplary embodiment of the disclosure.

Referring to FIG. 8, a semiconductor package 6 may differ from the semiconductor package 5 described with reference to FIG. 7 in that a first semiconductor chip 100_1 has a greater size than second to fourth semiconductor chips 200, 300, and 400. The first semiconductor chip 100_1 may have a portion not vertically overlapping with the second to fourth semiconductor chips 200, 300, and 400. A mold layer MD1 may cover a top surface of the first semiconductor chip 100_1. For example, the first semiconductor chip 100_1 may be a buffer chip, and the second to fourth semiconductor chips 200, 300, and 400 may be memory semiconductor chips. Although insulating layers AD1, AD2, and AD3 are shown in FIG. 8, the insulating layers AD1, AD2, and AD3 may be omitted. In this case, the mold layer MD1 may surround chip connection structures among the first to fourth semiconductor chips 100_1, 200, 300, and 400.

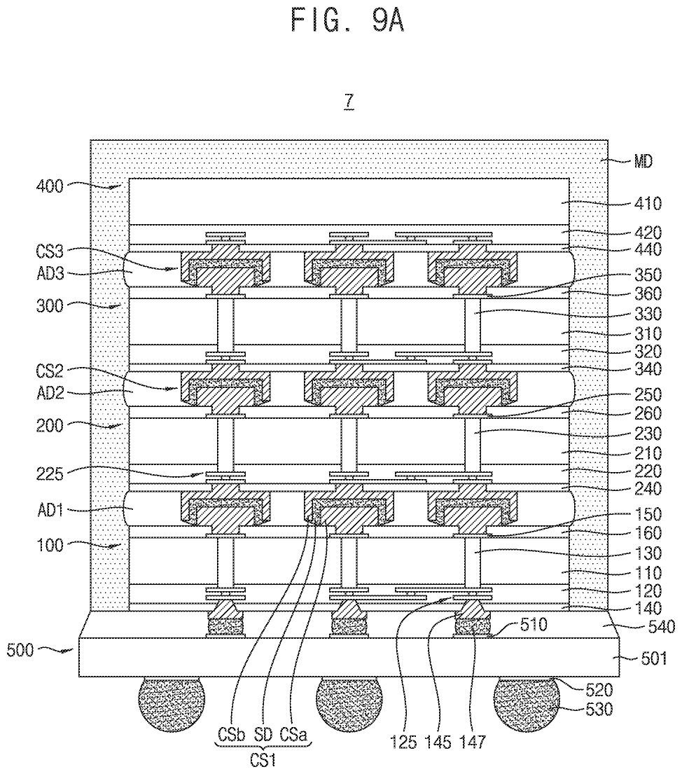

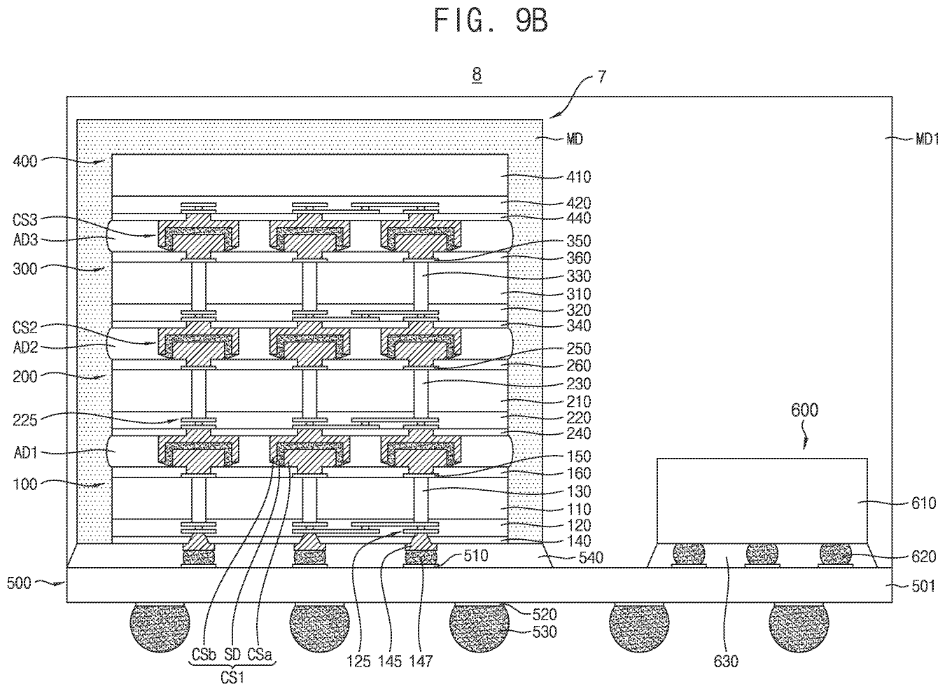

FIG. 9A is a sectional view of a semiconductor package according to an exemplary embodiment of the disclosure.

Referring to FIG. 9A, a semiconductor package 7 may include a base substrate 500 and an underfill material layer 540. For example, the base substrate 500 may be a printed circuit board, a ceramic substrate, or an interposer. When the base substrate 500 is a printed circuit board, the base substrate 500 may include a substrate body 501, a lower pad 520, an upper pad 510, and a solder resist layer (not shown) formed at bottom and top surfaces of the base substrate 500. An inner wiring, which electrically interconnects the lower pad 520 and the upper pad 510, may be formed in the substrate body 501.

When the base substrate 500 is an interposer, the base substrate 500 may include a substrate body 501 made of a semiconductor material, a lower pad 520, and an upper pad 510. For example, the substrate body 501 may be a silicon wafer. An inner wiring may be formed in the substrate body 501. A through via, which electrically interconnects the upper pad 510 and the lower pad 520, may be formed in the substrate body 501.

An outer connection terminal 530 may be disposed at the bottom surface of the base substrate 500. The outer connection terminal 530 may be disposed on the lower pad 520. For example, the outer connection terminal 530 may be a solder ball or a solder bump.

The upper pad 510, which is disposed at the top surface of the base substrate 500, may be connected to a connection terminal 147. A first semiconductor chip 100 may be mounted on the base substrate 500 via the connection terminal 147. The underfill material layer 540 may be interposed between the first semiconductor chip 100 and the base substrate 500 and, as such, may surround a side surface of the connection terminal 147. For example, the underfill material layer 540 may include an epoxy resin. In an exemplary embodiment, an insulating film constituted by a non-conductive film and flux may be formed between the base substrate 500 and the first semiconductor chip 100, in place of the underfill material layer 540.

FIG. 9B is a sectional view of a semiconductor package according to an exemplary embodiment of the disclosure.

Referring to FIG. 9B, a semiconductor package 8 may include a main semiconductor chip 600 disposed on a base substrate 500, a semiconductor package 7 disposed on the base substrate 500 while being spaced apart from the main semiconductor chip 600, and an outer mold layer MD1. The main semiconductor chip 600 may be a processor unit. The main semiconductor chip 600 may be a microprocessor unit (MPU) or a graphics processing unit (GPU). The main semiconductor chip 700 may be a package verified in association with normal operation thereof, that is, a known good package (KGP). A main connection terminal 720 may be disposed at a bottom surface of a body 610 of the main semiconductor chip 600. An underfill material layer 630 may surround the connection terminal 620 between the main semiconductor chip 600 and the base substrate 500. The outer mold layer MD1 may cover the semiconductor package 7 and the main semiconductor chip 600 on the base substrate 500. Although the semiconductor package 8 of FIG. 9B is shown as including, on the base substrate 500, the semiconductor package 7, which is described with reference to FIG. 9A, the semiconductor package 8 may include any one of the above-described semiconductor packages 1, 2, 3, 4, 5, and 6 on the base substrate 500.

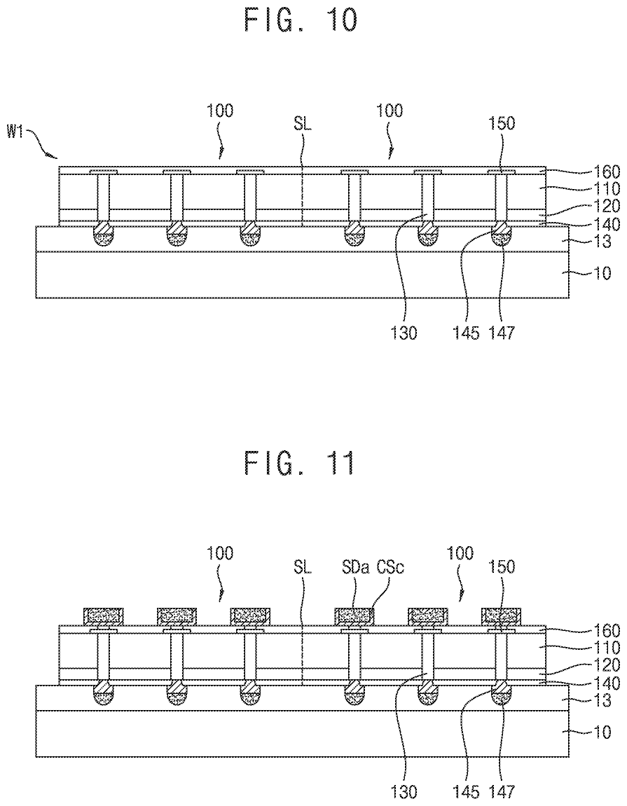

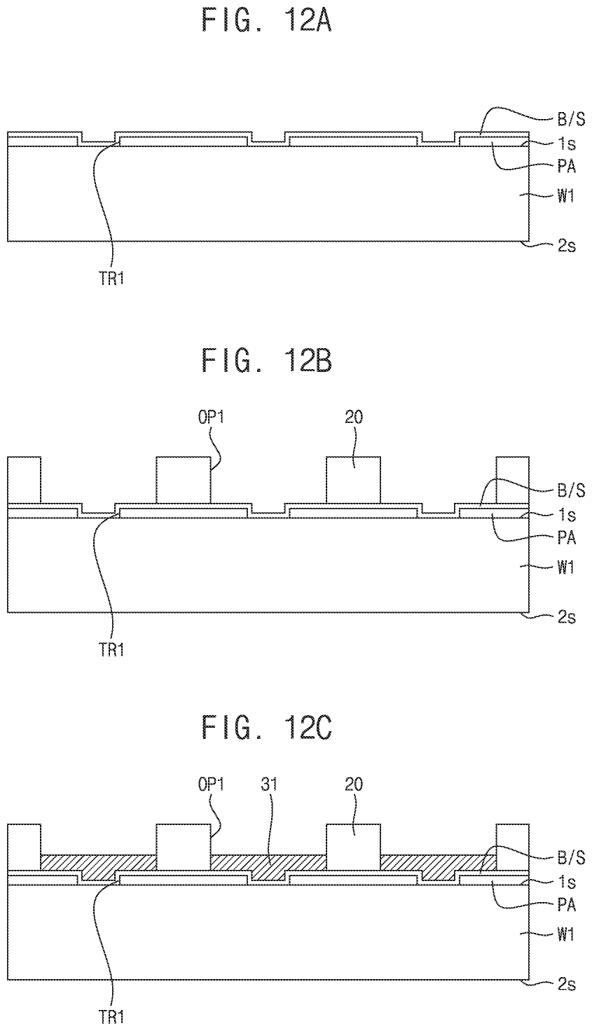

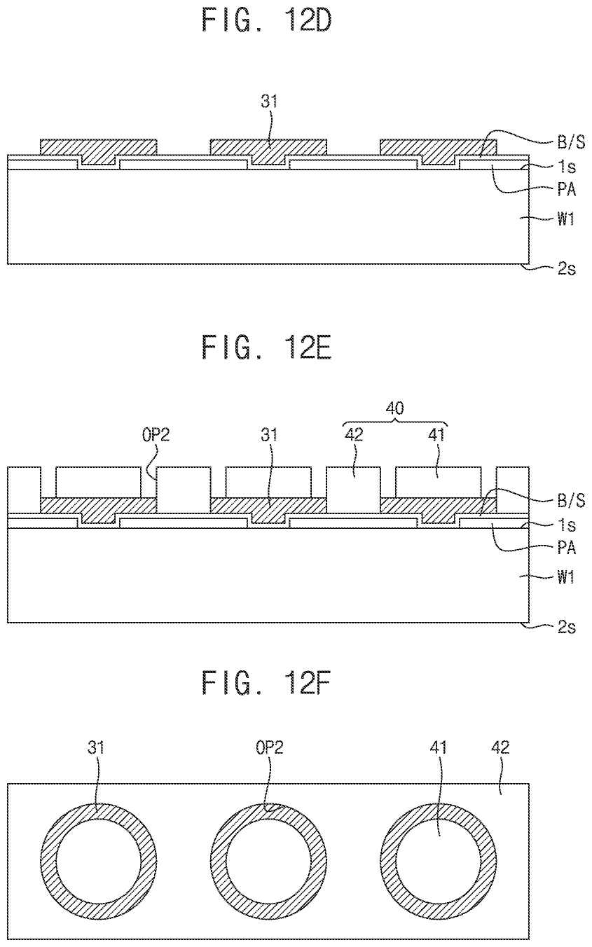

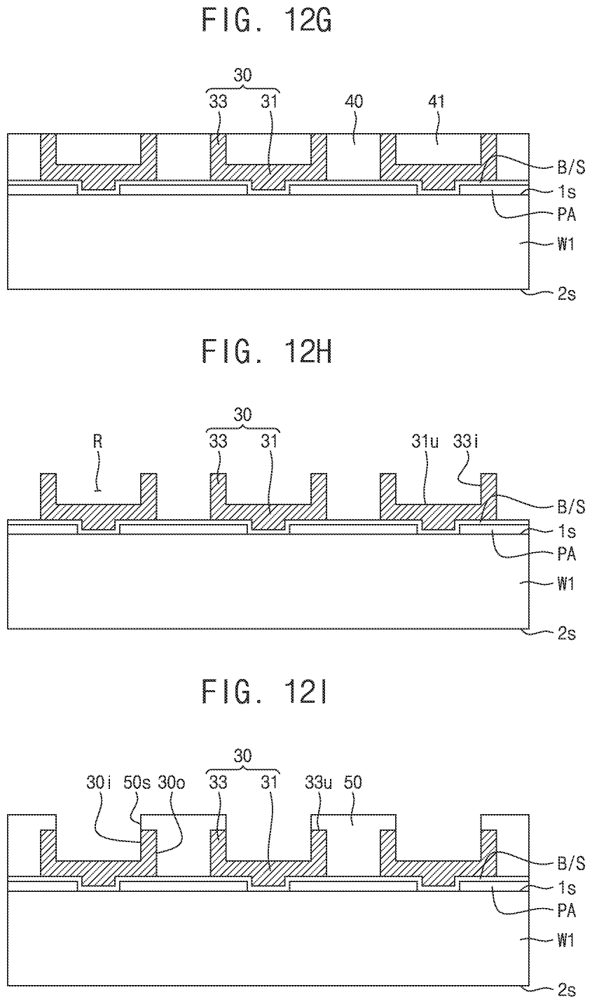

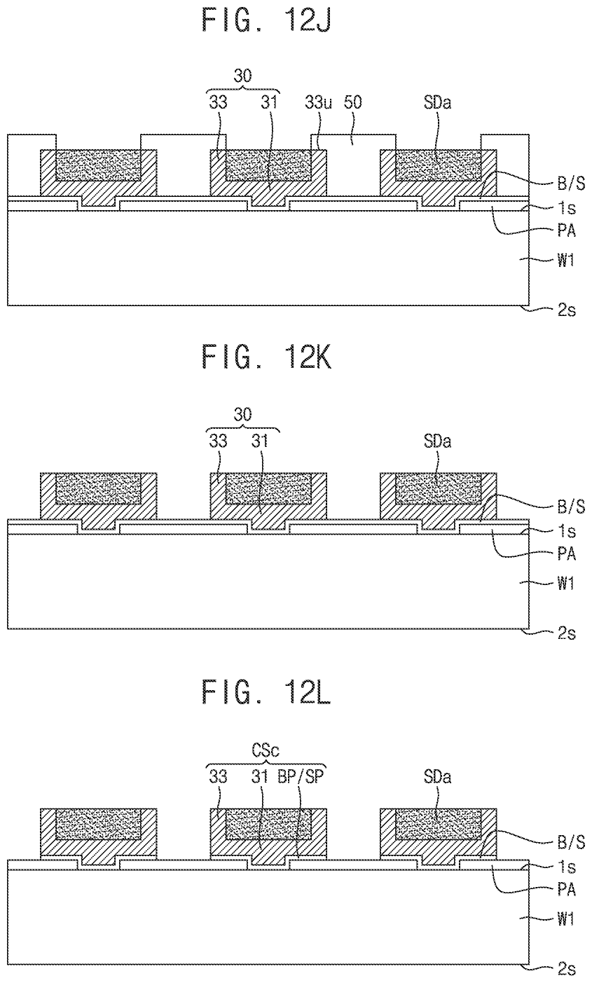

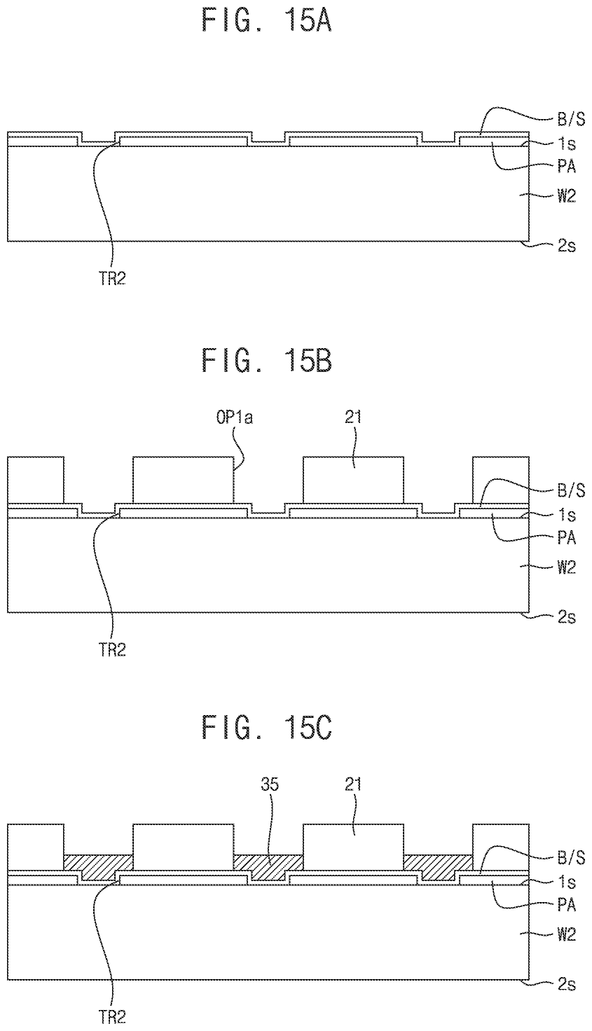

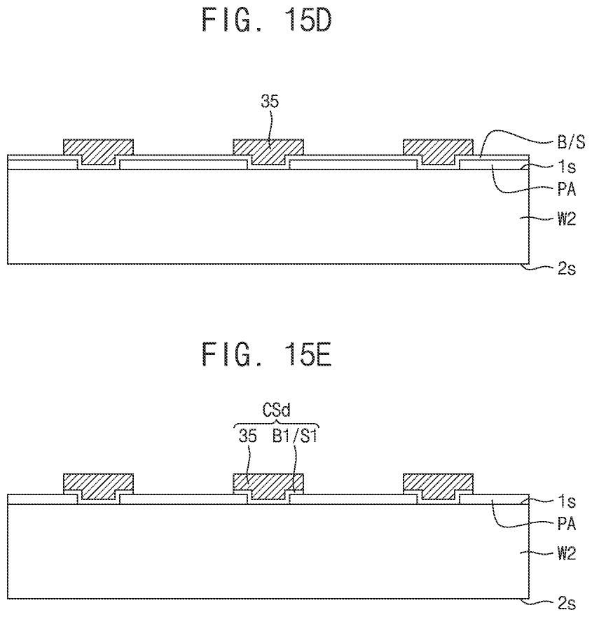

FIGS. 10 to 17 are sectional views for describing a semiconductor package manufacturing method according to an exemplary embodiment of the disclosure. FIGS. 12A to 12L are views for describing methods of manufacturing a recess connection structure and a contact layer in accordance with an exemplary embodiment of the disclosure. FIGS. 15A to 15E are sectional views for describing a method of manufacturing an insertion connection structure in accordance with an exemplary embodiment of the disclosure.

Referring to FIG. 10, a first semiconductor wafer W1 may be provided on a carrier substrate 10. The first semiconductor wafer W1 may be disposed on the carrier substrate 10 via an adhesive layer 13. The first semiconductor wafer W1 may include a plurality of first semiconductor chips 100 distinguished from one another by a scribe lane SL. The first semiconductor chip 100 may include a first semiconductor substrate 110, a first semiconductor element layer 120, a first through electrode 130, a first lower passivation layer 140, a lower connection structure 145, a connection terminal 147, a first upper pad 150, and a first upper passivation layer 160.

The first through electrode 130 may be formed to extend through the first semiconductor substrate 110 while extending through at least a portion of the first semiconductor element layer 120, and the first lower passivation layer 140 may be formed to cover a surface of the first semiconductor element layer 120. The lower connection structure 145 may be formed to extend through the first lower passivation layer 140, and the connection terminal 147 may be formed on the lower connection structure 145. The adhesive layer 13 may be formed to cover the connection terminal 147 and the lower connection structure 145, and the first semiconductor wafer W1 may be disposed on the carrier substrate 10 such that the adhesive layer 13, the connection terminal 147, and the lower connection structure 145 are directed to the carrier substrate 10. The first upper pad 150 and the first upper passivation layer 160 may be formed on a top surface of the first semiconductor substrate 110. After disposition of the first semiconductor wafer W1 on the carrier substrate 10, a surface directed to the carrier substrate 10 from among surfaces of the first semiconductor substrate 110 may be a bottom surface of the first semiconductor substrate 110, and a surface opposite to the bottom surface may be the top surface of the first semiconductor substrate 110.

Referring to FIG. 11, a first recess connection structure CSc and a first contact layer SDa may be formed on the first upper pad 150 and the first upper passivation layer 160. The first recess connection structure CSc and the first contact layer SDa may be formed in accordance with the recess connection structure manufacturing method described with reference to FIGS. 12A to 12L.

In FIGS. 12A to 12L, only a part of configurations of the semiconductor wafer W1 are shown for convenience of illustration and description. Referring to FIG. 12A, a semiconductor wafer W1 including a first surface 1s and a second surface 2s may be provided. Although not shown, the semiconductor wafer W1 may include a semiconductor element layer electrically connected to a through electrode extending through at least a portion of the semiconductor wafer W1. The semiconductor element layer may be disposed adjacent to the first surface is of the semiconductor wafer W1 and/or may be disposed adjacent to the second surface 2s of the semiconductor wafer W1.

A passivation layer PA may be formed on the first surface 1s of the semiconductor wafer W1. For example, when the semiconductor element layer is disposed adjacent to the first surface 1s, the passivation layer PA may be referred to as a lower passivation layer, whereas, when the semiconductor element layer is disposed adjacent to the second surface 2s, the passivation layer PA may be referred to as an upper passivation layer.

A trench TR1 may be formed by partially etching the passivation layer PA. An upper pad (not shown) may be exposed by the trench TR1, or a top surface of the semiconductor element layer (not shown) may be exposed by the trench TR1. A barrier layer B and a seed layer S may be formed on the passivation layer PA through a sputtering process. Although the barrier layer B and the seed layer S are shown in FIG. 12A as a single layer B/S, due to the scale of the drawing, the barrier layer B and the seed layer S may be two different layers. The barrier layer B may be formed on the passivation layer PA, and the seed layer S may be formed on the barrier layer B. The barrier layer B and the seed layer S may also be formed in the trench TR1. For example, the barrier layer B may include titanium (Ti), and the seed layer S may include copper (Cu).

Referring to FIG. 12B, a first photoresist pattern 20 may be formed. The first photoresist pattern 20 may have openings OP1. The openings OP1 may be spaced apart from one another by the first photoresist pattern 20. The first photoresist pattern 20 may expose a portion of the seed layer S through the opening OP1. The opening OP1 may be formed to vertically overlap with the trench TR1. For example, the opening OP1 may have a shape such as a circular shape, a quadrangular shape, a hexagonal shape, an octagonal shape, etc. when viewed in a top view.

Referring to FIG. 12C, a plurality of first preliminary connection structures 31 may be formed through an electroplating process. The first preliminary connection structure 31 may be formed on the seed layer S in the opening OP1. The first preliminary connection structure 31 may completely fill the trench TR1. The first preliminary connection structure 31 may incompletely fill the opening OP1. The level of a top surface of the first preliminary connection structure 31 may be disposed to be lower than the level of a top surface of the first photoresist pattern 20 with reference to the first surface 1s of the semiconductor wafer W1. For example, the first preliminary connection structure 31 may include nickel (Ni) or copper (Cu). For example, the first preliminary connection structure 31 may have a shape such as a circular shape, a quadrangular shape, a hexagonal shape, an octagonal shape, etc. when viewed in a top view.

Referring to FIG. 12D, the first photoresist pattern 20 may be removed. A top surface of the seed layer S may be exposed among the first preliminary connection structures 31. For example, the first photoresist pattern 20 may be removed by an ashing process and/or a stripping process.

FIG. 12F is a plan view corresponding to FIG. 12E. Referring to FIGS. 12E and 12F, a second photoresist pattern 40 may be formed. The second photoresist pattern 40 may include a first pattern 41 and a second pattern 42. The first pattern 41 may be formed on the first preliminary connection structure 31. The first pattern 41 may cover a portion of the top surface of the first preliminary connection structure 31 while exposing another portion of the top surface of the first preliminary connection structure 31. The first pattern 41 may expose an edge of the first preliminary connection structure 31. The second pattern 42 may be spaced apart from the first pattern 41. The second pattern 42 may be formed on the seed layer S exposed by the first preliminary connection structure 31. The second pattern 42 may be formed to contact a side surface of the first preliminary connection structure 31. The second photoresist pattern 40 may have an opening OP2. The opening OP2 may be defined by a side surface of the first pattern 41, a side surface of the second pattern 42, and the top surface of the first preliminary connection structure 31. An edge of the top surface of the first preliminary connection structure 31 may be exposed through the opening OP2. The opening OP2 may have a ring shape when viewed in a top view. Although the opening OP2 is shown in the drawing as having a circular ring shape, the exemplary embodiments of the disclosure are not limited thereto, and the opening OP2 may have various ring shapes such as a quadrangular ring shape, an octagonal ring shape, etc. When viewed in a top view, the shape of the opening OP2 may correspond to the shape of the first preliminary connection structure 31.

Referring to FIG. 12G, a second preliminary connection structure 33 may be formed. The second preliminary connection structure 33 may be formed in the opening OP2. The second preliminary connection structure 33 may completely fill the opening OP2. The second preliminary connection structure 33 may be formed through an electroplating process using the first preliminary connection structure 31 exposed in the opening OP2 as a seed layer. The second preliminary connection structure 33 may have a shape protruding upwards from the edge of the first preliminary connection structure 31. The second preliminary connection structure 33 may have a ring shape when viewed in a top view. The first preliminary connection structure 31 and the second preliminary connection structure 33 may be coupled to each other, thereby forming a preliminary recess connection structure 30.

Referring to FIG. 12H, the second photoresist pattern 40 may be removed. As the second photoresist pattern 40 is removed, the seed layer S may be exposed. As the second photoresist pattern 40 is removed, surfaces of the first preliminary connection structure 31 and the second preliminary connection structure 33 may be completely exposed. For example, the second photoresist pattern 40 may be removed by an ashing process and/or a stripping process. The preliminary recess connection structure 30 may have a recess R defined by a top surface 31u of the first preliminary connection structure 31 and an inner side surface 33i of the second preliminary connection structure 33. The inner side surface 33i of the second preliminary connection structure 33 may be referred to as an inner surface of the preliminary recess connection structure 30.

Referring to FIG. 12I, a third photoresist pattern 50 may be formed. The third photoresist pattern 50 may be formed on the seed layer S exposed among preliminary recess connection structures 30. The third photoresist pattern 50 may cover an outer side surface 30o of the preliminary recess connection structure 30. The third photoresist pattern 50 may cover a top surface 33u of the second preliminary connection structure 33. The third photoresist pattern 50 may be omitted in the recess R of the preliminary recess connection structure 30. A side surface 50s of the third photoresist pattern 50 may be aligned with an inner side surface 30i of the preliminary recess connection structure 30. The side surface 50s of the third photoresist pattern 50 may be coplanar with the inner side surface 30i of the preliminary recess connection structure 30.

Referring to FIG. 12J, a contact layer SDa may be formed in the recess R of the preliminary recess connection structure 30. The contact layer SDa may be a solder. The contact layer SDa may be formed through an electroplating process or an electroless plating process. The level of a top surface of the contact layer SDa may be equal to or lower than the level of the top surface 33u of the second preliminary connection structure 33.

Referring to FIG. 12K, the third photoresist pattern 50 may be removed. As the third photoresist pattern 50 is removed, the seed layer S may be exposed. As the third photoresist pattern 50 is removed, a side surface of the preliminary recess connection structure 30 may be exposed. As the third photoresist pattern 50 is removed, a top surface of the second preliminary connection structure 33 may be exposed.

Referring to FIG. 12L, the seed layer S and the barrier layer B may be partially etched, thereby forming a recess connection structure CSc. The seed layer S and the barrier layer B may be etched using the contact layer SDa and the preliminary recess connection structure 30 as an etch mask. The seed layer S and the barrier layer B, which are not covered by the preliminary recess connection structure 30, may be etched, thereby forming a seed pattern SP and a barrier pattern BP. As the seed layer S and the barrier layer B are partially etched, the recess connection structure CSc, which includes the seed pattern SP, the barrier pattern BP and the preliminary recess connection structure 30, may be formed.

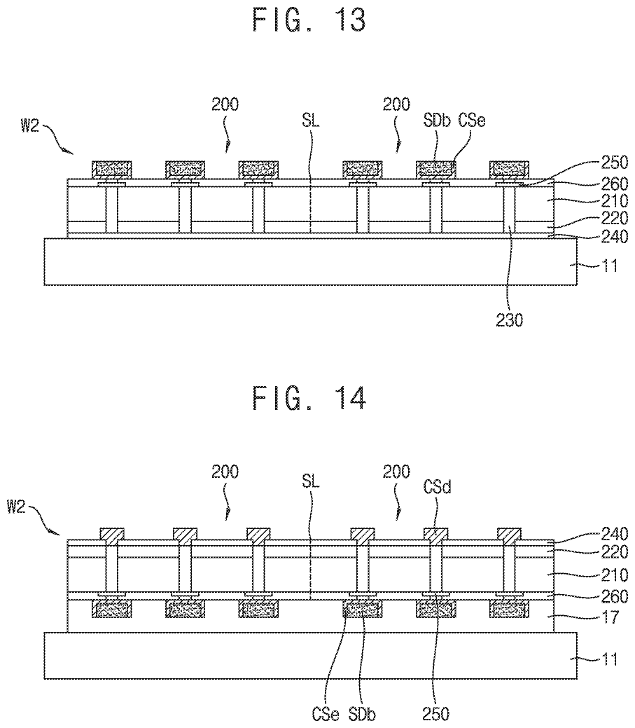

Referring to FIG. 13, a second semiconductor wafer W2 may be provided on a carrier substrate 11. The second semiconductor wafer W2 may include a plurality of second semiconductor chips 200 distinguished from one another by a scribe lane SL. The second semiconductor chip 200 may include a second semiconductor substrate 210, a second semiconductor element layer 220, a second through electrode 230, a second lower passivation layer 240, a second upper pad 250, and a second upper passivation layer 260.

A second recess connection structure CSe and a second contact layer SDb may be formed on the second upper pad 250 and the second upper passivation layer 260. The second recess connection structure CSe and the second contact layer SDb may be formed in accordance with the recess connection structure manufacturing method described with reference to FIGS. 12A to 12L.

Referring to FIG. 14, the second semiconductor wafer W2, which is formed with the second recess connection structure CSe and the second contact layer SDb, may be inverted, and may then be disposed on the carrier substrate 11. The second semiconductor wafer W2 may be disposed on the carrier substrate 11 via an adhesive layer 17. The second semiconductor wafer W2 may be disposed such that the second recess connection structure CSe and the second contact layer SDb are directed to the carrier substrate 11. The adhesive layer 17 may be directly disposed on the carrier substrate 11 while covering the second recess connection structure CSe and the second contact layer SDb. The second lower passivation layer 240 may be disposed relatively farther from the carrier substrate 11 than the second upper passivation layer 260.

A first insertion connection structure CSd may be formed on the second lower passivation layer 240. The first insertion connection structure CSd may extend through the second lower passivation layer 240. The first insertion connection structure CSd may be electrically connected to the second semiconductor element layer 220 and/or the second through electrode 230. The first insertion connection structure CSd may be formed in accordance with the insertion connection structure manufacturing method described with reference to FIGS. 15A to 15E. After formation of the first insertion connection structure CSd, the semiconductor wafer W2 may be diced along the scribe lane SL, thereby individualizing second semiconductor chips 200.

In FIGS. 15A to 15E, only a part of configurations of the semiconductor wafer W2 are shown for convenience of illustration and description. Referring to FIG. 15A, the semiconductor wafer W2, which includes a first surface 1s and a second surface 2s, may be provided. Although not shown, the semiconductor wafer W2 may include a semiconductor element layer electrically connected to a through electrode extending through at least a portion of the semiconductor wafer W2. The semiconductor element layer may be disposed adjacent to the first surface is of the semiconductor wafer W2 and/or may be disposed adjacent to the second surface 2s of the semiconductor wafer W2.

A passivation layer PA may be formed on the first surface 1s of the semiconductor wafer W2. For example, when the semiconductor element layer is disposed adjacent to the first surface 1s, the passivation layer PA may be referred to as a lower passivation layer, whereas, when the semiconductor element layer is disposed adjacent to the second surface 2s, the passivation layer PA may be referred to as an upper passivation layer. For example, when the first insertion connection structure CSd shown in FIG. 14 is formed, the semiconductor element layer 220 may be disposed adjacent to the first surface 1s, and the passivation layer PA may correspond to the second lower passivation layer 240.

A trench TR2 may be formed by partially etching the passivation layer PA. A portion of the semiconductor element layer (not shown) may be exposed by the trench TR2. A barrier layer B and a seed layer S may be formed on the passivation layer PA through a sputtering process. The barrier layer B and the seed layer S may also be formed in the trench TR2. The barrier layer B may be formed on the passivation layer PA, and the seed layer S may be formed on the barrier layer B. For example, the barrier layer B may include titanium (Ti), and the seed layer S may include copper (Cu).

Referring to FIG. 15B, a photoresist pattern 21 may be formed. The photoresist pattern 21 may have openings OP1a. The openings OP1a may be spaced apart from one another by the photoresist pattern 21. The photoresist pattern 21 may expose a portion of the seed layer S through the opening OP1a. The opening OP1a may be formed to vertically overlap with the trench TR2.

Referring to FIG. 15C, a preliminary connection structure 35 may be formed through an electroplating process. The preliminary connection structure 35 may be formed on the seed layer S in the opening OP1a. The preliminary connection structure 35 may completely fill the trench TR2. The preliminary connection structure 35 may incompletely fill the opening OP1a. The level of a top surface of the preliminary connection structure 35 may be disposed to be lower than the level of a top surface of the photoresist pattern 21 with reference to the first surface 1s of the semiconductor wafer W2. For example, the preliminary connection structure 35 may include nickel (Ni).

Referring to FIG. 15D, the photoresist pattern 21 may be removed. A top surface of the seed layer S may be exposed among preliminary connection structures 35. For example, the photoresist pattern 21 may be removed by an ashing process and/or a stripping process.

Referring to FIG. 15E, the seed layer S and the barrier layer B may be partially etched, thereby forming an insertion connection structure CSd. The seed layer S and the barrier layer B may be etched using the insertion connection structure CSd as an etch mask. As the seed layer S and the barrier layer B, which are not covered by the insertion connection structure CSd, are etched, a seed pattern S1 and a barrier pattern B1 may be formed. As the seed layer S and the barrier layer B are partially etched, the insertion connection structure CSd, which includes the seed pattern S1, the barrier pattern B1 and the preliminary insertion connection structure 35, may be formed.

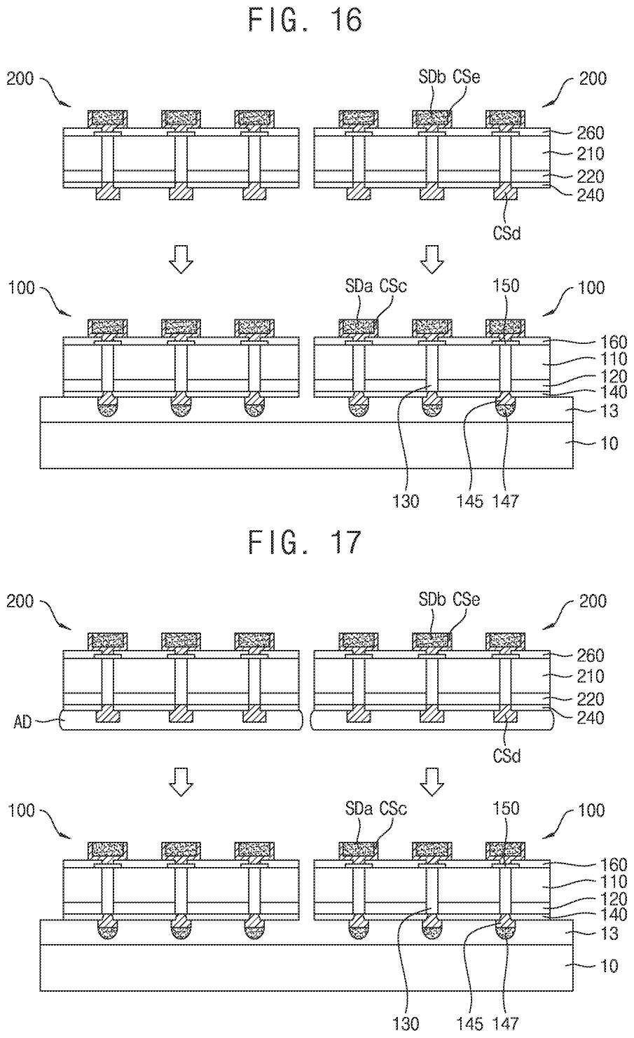

Referring to FIG. 16, the semiconductor wafer W1, which has been completely subjected to the process described with reference to FIG. 11, may be diced along the scribe lane SL, thereby individualizing first semiconductor chips 100. The second semiconductor chips 200, which have been completely subjected to the process described with reference to FIG. 14, may be mounted on the individualized first semiconductor chips 100. The second semiconductor chip 200 may be mounted on the first semiconductor chip 100 in a state in which the first insertion connection structure CSd is directed to the first semiconductor chip 100. A bonding process may be performed such that the first insertion connection structure CSd connected to the second semiconductor chip 200 corresponds to the first contact layer SDa on the first semiconductor chip 100. For example, the first insertion connection structure CDd may be connected to the first contact layer SDa by a reflow process or a thermal compression process. Thereafter, a third semiconductor chip and a fourth semiconductor chip may be formed through repeated execution of a process identical to the above-described process of forming the second semiconductor chip 200, and may then be mounted on the second semiconductor chip. Subsequently, a molding process of forming a mold layer covering the semiconductor chips may be performed.

Referring to FIG. 17, the bonding process may be performed in a state in which an insulating layer AD covers the first insertion connection structure CSd.

In accordance with exemplary embodiments of the disclosure, it may be possible to provide a semiconductor package in which contact reliability of a chip connection structure among stacked semiconductor chips is enhanced.

While the embodiments of the disclosure have been described with reference to the accompanying drawings, it should be understood by those skilled in the art that various changes and modifications may be made without departing from the scope of the disclosure and without changing essential features thereof. Therefore, the above-described embodiments should be considered in a descriptive sense only and not for purposes of limitation.

What is claimed is:

1. A semiconductor package comprising:
a first semiconductor chip;
a second semiconductor chip on the first semiconductor chip; and
a first chip connection structure disposed between the first semiconductor chip and the second semiconductor chip,
wherein the first chip connection structure comprises
a first insertion connection structure connected to the first semiconductor chip,
a first recess connection structure connected to the second semiconductor chip, and
a first contact layer interposed between the first insertion connection structure and the first recess connection structure,
wherein the first recess connection structure comprises a base and a side wall which defines a recess,
wherein a portion of the first insertion connection structure is disposed in the recess,
wherein a portion of the first contact layer is disposed in the recess, and the first contact layer covers at least a portion of a bottom surface of the side wall.

2. The semiconductor package according to claim 1, wherein the first contact layer completely covers a side surface of the first insertion connection structure.

3. The semiconductor package according to claim 1, wherein the first contact layer is spaced apart from the first semiconductor chip.

4. The semiconductor package according to claim 1, wherein the first contact layer comprises a lowermost surface having an inclination.

5. The semiconductor package according to claim 4, wherein the lowermost surface of the first contact layer interconnects a side surface of the first insertion connection structure and the bottom surface of the side wall.

6. The semiconductor package according to claim 4, wherein the lowermost surface of the first contact layer is a curved surface.

7. The semiconductor package according to claim 4, wherein the lowermost surface of the first contact layer forms an acute angle with a top surface of the first semiconductor chip.

8. The semiconductor package according to claim 1, wherein a minimum distance between the bottom surface of the side wall and the first semiconductor chip is about 2 to 20 μm.

9. The semiconductor package according to claim 1, wherein:
the first insertion connection structure comprises a first section and a second section; and
a height of the second section is equal to or smaller than a height of the side wall.

10. The semiconductor package according to claim 1, further comprising:
a third semiconductor chip disposed on the second semiconductor chip; and
a second chip connection structure disposed between the second semiconductor chip and the third semiconductor chip,
wherein the second chip connection structure comprises
a second recess connection structure connected to the second semiconductor chip,
a second insertion connection structure connected to the third semiconductor chip, and
a second contact layer interposed between the second recess connection structure and the second insertion connection structure.

11. A semiconductor package comprising:
a first semiconductor chip;
a second semiconductor chip on the first semiconductor chip;
a first chip connection structure disposed between the first semiconductor chip and the second semiconductor chip; and
a mold layer covering the first semiconductor chip and the second semiconductor chip,
wherein the first chip connection structure comprises
a first recess connection structure connected to the first semiconductor chip,
a first insertion connection structure connected to the second semiconductor chip, and
a first contact layer interposed between the first recess connection structure and the first insertion connection structure,
wherein the first recess connection structure comprises a base and a side wall which defines a recess,
wherein a portion of the first insertion connection structure is disposed in the recess,
wherein a portion of the first contact layer is disposed in the recess, and the first contact layer covers at least a portion of a top surface of the side wall while being spaced apart from a bottom surface of the second semiconductor chip.

12. The semiconductor package according to claim 1, wherein:
the first insertion connection structure comprises a first section, and a second section disposed on the first section, a portion of the second section being disposed in the recess; and
a width of the second section is greater than a width of the first section.

13. The semiconductor package according to claim 12, wherein the first contact layer completely covers a side surface of the second section.

14. The semiconductor package according to claim 11, wherein the first contact layer comprises an uppermost surface having an inclination.

15. The semiconductor package according to claim 14, wherein:
the second semiconductor chip comprises a semiconductor element layer, and a lower passivation layer on the semiconductor element layer; and
the uppermost surface of the first contact layer is spaced apart from the lower passivation layer.

16. The semiconductor package according to claim 15, wherein the uppermost surface of the first contact layer forms an acute angle with the lower passivation layer.

17. The semiconductor package according to claim 15, wherein the mold layer is interposed between the uppermost surface of the first contact layer and the lower passivation layer.

18. The semiconductor package according to claim 11, further comprising:
an insulating layer disposed between the first semiconductor chip and the second semiconductor chip,
wherein the insulating layer surrounds the first chip connection structure.

19. The semiconductor package according to claim 11, further comprising:
a third semiconductor chip on the second semiconductor chip; and
a second chip connection structure between the second semiconductor chip and the third semiconductor chip,
wherein the second chip connection structure comprises
a second insertion connection structure connected to the second semiconductor chip,
a second recess connection structure connected to the third semiconductor chip, and
a second contact layer interposed between the second insertion connection structure and the second recess connection structure.

20. A semiconductor package comprising:
a base substrate;
a first semiconductor chip on the base substrate;
a second semiconductor chip on the first semiconductor chip;
a third semiconductor chip on the second semiconductor chip;
a first chip connection structure between the first semiconductor chip and the second semiconductor chip;
a second chip connection structure between the second semiconductor chip and the third semiconductor chip; and
a mold layer disposed on the base substrate while covering the first semiconductor chip, the second semiconductor chip, and the third semiconductor chip,
wherein one of the first chip connection structure and the second chip connection structure comprises
an insertion connection structure,
a recess connection structure on the insertion connection structure, and
a contact layer between the insertion connection structure and the recess connection structure,
wherein the first chip connection structure and the second chip connection structure have mirror symmetry with respect to each other.
